(19) United States
(12) Patent Application Publication
(10) Pub. No.: US 2011/0269309 A1
(43) Pub. Date: Nov. 3, 2011

(54) PHOTORESIST COMPOSITION, METHOD OF FORMING PATTERN BY USING THE PHOTORESIST COMPOSITION, AND METHOD OF MANUFACTURING THIN-FILM TRANSISTOR SUBSTRATE

(75) Inventors: Pil-Soon HONG, Hwaseong-si (KR); Gwui-Hyun PARK, Osan-si (KR); Jin-Ho JU, Seoul (KR); Jean-Ho SONG, Yongin-si (KR); Sang-Tae KIM, Iksan-si (KR); Seong-Hyeon KIM, Iksan-si (KR); Won-Young CHANG, Iksan-si (KR); Jong-Heum YOON, Iksan-si (KR); Eun-Sang LEE, Iksan-si (KR); Min-Ju IM, Iksan-si (KR)

(73) Assignees: DONGWOO FINE-CHEM CO., LTD, Iksan-si (KR); SAMSUNG ELECTRONICS CO., LTD., Suwon-si (KR)

(21) Appl. No.: 12/981,304

(22) Filed: Dec. 29, 2010

(30) Foreign Application Priority Data
Apr. 30, 2010 (KR) 10-2010-0040837

(51) Int. Cl. H01L 21/3213; G03F 7/20; G03F 7/004

(52) U.S. Cl. 438/656; 430/281.1; 430/325; 257/E21.305

(57) ABSTRACT

Provided are a photoresist composition having superior adhesion to an etch target film, a method of forming a pattern by using the photoresist composition, and a method of manufacturing a thin-film transistor (TFT) substrate. The photoresist composition includes an alkali-soluble resin; a photosensitive compound; a solvent; and 0.01 to 0.1 parts by weight of a compound represented by Formula 1:

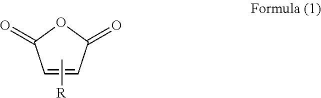

wherein R is one of hydrogen, an alkyl having 1 to 10 carbon atoms, a cycloalkyl having 4 to 8 carbon atoms, and a phenyl group.

### CROSS REFERENCE TO RELATED APPLICATION

This application claims priority from and the benefit of Korean Patent Application No. 10-2010-0040837, filed on Apr. 30, 2010, which is hereby incorporated by reference for all purposes as if fully set forth herein.

### BACKGROUND OF THE INVENTION

1. Field of Invention

Exemplary embodiments of the present invention relate to a photoresist composition, a method of forming a pattern by using the photoresist composition, and a method of manufacturing a thin-film transistor (TFT) substrate, and more particularly, to a photoresist composition having superior adhesion to an etch target film, a method of forming a pattern by using the photoresist composition, and a method of manufacturing a TFT substrate.

2. Discussion of the Background

In a process of manufacturing printed circuit boards and substrates of semiconductor wafers and liquid crystal display (LCD) panels, a complicated circuit pattern is typically formed on a top surface of a base substrate such as an insulating substrate or a glass substrate. To form the circuit pattern, a photolithography technique is widely used.

According to the photolithography technique, a photoresist film is formed on a base substrate and is exposed to light by using a photomask that has a mask pattern corresponding to a circuit pattern. The exposed photoresist film is developed to form a photoresist pattern. Then, an etch target film is etched using the photoresist pattern as a mask, thereby forming a pattern of a desired shape on the base substrate.

When there is poor adhesion between the photoresist pattern and the etch target film, an etching solution may penetrate into an interface between the photoresist pattern and the etch target film. This may reduce a taper angle of an etch target pattern.

### SUMMARY OF THE INVENTION

Exemplary embodiments of the present invention provide a photoresist composition having superior adhesion to an etch target film.

Exemplary embodiments of the present invention also provide a method of forming a pattern by using a photoresist composition having superior adhesion to an etch target film.

Exemplary embodiments of the present invention also provide a method of manufacturing a thin-film transistor (TFT) substrate by using a photoresist composition having superior adhesion to an etch target film.

Additional features of the invention will be set forth in the description which follows, and in part will be apparent from the description, or may be learned by practice of the invention.

An exemplary embodiment of the present invention discloses a photoresist composition that includes an alkali-soluble resin; a photosensitive compound; a solvent; and 0.01 to 0.1 parts by weight of a compound represented by Formula 1:

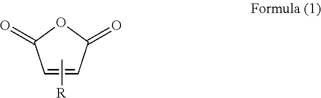

wherein R is one of hydrogen, an alkyl having 1 to 10 carbon atoms, a cycloalkyl having 4 to 8 carbon atoms, and a phenyl group. An exemplary embodiment of the present invention also discloses a method of forming a pattern that includes forming a photoresist film by coating an etch target film with a photoresist composition that includes an alkali-soluble resin, a photosensitive compound, a solvent, and 0.01 to 0.1 parts by weight of a compound represented by Formula 1; exposing the photoresist film to light; forming a photoresist pattern by developing the photoresist film; and etching the etch target film by using the photoresist pattern as an etch mask.

An exemplary embodiment of the present invention further discloses a method of manufacturing a TFT substrate that includes sequentially forming a semiconductor layer and a wiring film on a substrate; forming a photoresist film by coating the wiring film with a photoresist composition which includes an alkali-soluble resin, a solvent, and a photosensitive compound, 0.01 to 0.1 parts by weight of a compound represented by Formula 1; forming a photoresist pattern, which comprises a first region and a second region thicker than the first region and formed on both sides of the first region, by exposing the photoresist film to light and developing the exposed photoresist film; performing a first etching of the wiring film and the semiconductor layer by using the photoresist pattern as an etch mask; removing the first region of the photoresist pattern; and performing a second etching of the wiring film and the semiconductor layer again by using the second region of the photoresist pattern, which remains on the wiring film, as an etch mask.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1, FIG. 2, FIG. 3, FIG. 4, and FIG. 5 are cross-sectional views of a method of forming a pattern according to an exemplary embodiment of the present invention.

FIG. 6 is a layout view of a thin-film transistor (TFT) substrate manufactured using a manufacturing method according to an exemplary embodiment of the present invention.

FIG. 7 is a cross-sectional view of the TFT substrate taken along line A-A′ of FIG. 6.

FIG. 8, FIG. 9, FIG. 10, FIG. 11, FIG. 12, FIG. 13, FIG. 14, and FIG. 15 are cross-sectional views of a method of manufacturing the TFT substrate shown in FIG. 6.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

Spatially relative terms, such as “below”, “beneath”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “beneath” other elements or features would then be oriented “above” the other elements or features. Thus, the exemplary term “below” or “beneath” can encompass both an orientation of above and below. The device may be otherwise oriented and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated components, steps, operations, and/or elements, but do not preclude the presence or addition of one or more other components, steps, operations, elements, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a photoresist composition according to an exemplary embodiment of the present invention will be described in detail.

A photoresist composition according to an exemplary embodiment of the present invention includes an alkali-soluble resin, a photosensitive compound, a solvent, and 0.01 to 0.1 parts by weight of a compound represented by Formula 1:

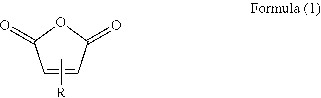

where R is hydrogen, an alkyl having 1 to 10 carbon atoms, a cycloalkyl having 4 to 8 carbon atoms, or a phenyl group.

The alkali-soluble resin is soluble in an alkaline solution such as an aqueous alkaline developing solution but is insoluble in water. The alkali-soluble resin is not limited to a particular resinous composition and may be any resin well known in the art to which the present invention pertains. Examples of the alkali-soluble resin include novolac resin, polyvinyl alcohol, polyvinyl alkyl ether, a copolymer of styrene and acrylic acid, a copolymer of methacrylic acid and methacrylic acid alkyl ester, a hydroxystyrene polymer, polyvinyl hydroxybenzoate, and polyvinyl hydroxybenzene.

A novolac resin may preferably be used as the alkali-soluble resin. The novolac resin may be obtained by an addition-condensation reaction of a phenolic compound with an aldehyde compound. The phenolic compound used to prepare the novolac resin may include one of or a mixture of two or more of phenol, o-cresol, m-cresol, p-cresol, 2,5-xylenol, 3,5-xylenol, 3,4-xylenol, 2,3,5-trimethylphenol, 4-t-butylphenol, 2-t-butylphenol, 3-t-butylphenol, 3-ethylphenol, 2-ethylphenol, 4-ethylphenol, 3-methyl-6-t-butylephenol, 4-methyl-2-t-butylphenol, 2-naftol, 1,3-dihydroxynaftalen, 1,7-dihydroxnaftalen, and 1,5-dihydroxynaftalen.

The aldehyde compound used to prepare the novolac resin may include one of or a mixture of two or more of formaldehyde, paraformaldehyde, acetaldehyde, propyl aldehyde, benzaldehyde, phenylaldehyde, α-phenylpropylaldehyde, β-phenylpropylaldehyde, o-hydroxybenzaldehyde, m-hydroxybenzaldehyde, p-hydroxybenzaldehyde, glutaraldehyde, glyoxal, o-methylbenzaldehyde, and p-methylbenzaldehyde.

The addition-condensation reaction of the phenol compound with the aldehyde compound for preparing the novolac resin may be performed using a conventional method in the presence of an acid catalyst. Here, the reaction temperature may be approximately 60 to 250° C., and the reaction time may be approximately 2 to 30 hours. Examples of the acid catalyst include organic acids such as oxalic acid, formic acid, trichloroacetic acid, p-toluenesulfonic acid, and oxalic acid; inorganic acids such as hydrochloric acid, sulfuric acid, perchloric acid, and phosphoric acid; and divalent metal salts such as zinc acetate and magnesium acetate.

The addition-condensation reaction of the phenol compound with the aldehyde compound for preparing the novolac resin may be performed in an appropriate solvent or in a bulk phase.

To enhance photoresist performance, high, middle, or low molecular weight molecules may be removed from the novolac resin prepared by the addition-condensation reaction. Consequently, a novolac resin having an appropriate molecular weight for its use can be prepared.

The alkali-soluble resin may be added at 10 to 30 parts by weight based on 100 parts by weight of the photoresist composition. The added alkali-soluble resin may offer advantages in terms of resolution and profile shape.

The photosensitive compound is not limited to a particular one and may be any photosensitive compound well known in the art to which the present invention pertains. Examples of the photosensitive compound include a diazide compound.

The diazide compound is not limited to a particular one and may be any diazide compound used as a photosensitizer and well known in the art to which the present invention pertains. For example, the diazide compound may include one of or a mixture of two or more of poly-hydroxybenzophenone, 1,2-naphtoquinonediazide, 2-diazo-1-naphthol-5-sulfonic acid, 2-diazo-1-naphthol-4-sulfonic acid, 2,3,4,4′-tetrahydroxybenzophenone, and naphthoquinone-1,2-diazide-5-sulfonyl chloride.

The photosensitive compound may be added at 1 to 15 parts by weight based on 100 parts by weight of the photoresist composition. The photosensitive compound added at 1 to 15 parts by weight based on 100 parts by weight of the photoresist composition may offer advantages in terms of sensitivity, resolution, and profile shape.

The compound of Formula 1 may improve the adhesion of the photoresist composition to an etch target film. The compound of Formula 1 is represented by:

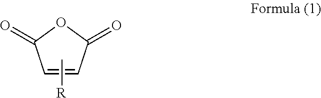

where R is hydrogen, an alkyl having 1 to 10 carbon atoms, a cycloalkyl having 4 to 8 carbon atoms, or a phenyl group.

When R is hydrogen, the compound of Formula 1 is maleic anhydride. When R is a phenyl group, the compound of Formula 1 is phthalic anhydride.

The compound of Formula 1 is not limited to a particular one. However, phthalic anhydride, in which R is a phenyl group in Formula 1, may be preferred.

The compound of Formula 1 may be added at 0.01 to 0.1 parts by weight based on 100 parts by weight of the photoresist composition. The compound of Formula 1 may preferably added at 0.03 to 0.07 parts by weight. When the compound of Formula 1 is added at 0.01 to 0.1 parts by weight based on 100 parts by weight of the photoresist composition, the adhesion between the photoresist composition and the etch target film may be superior. However, when the compound of Formula 1 is added at less than 0.01 parts by weight based on 100 parts by weight of the photoresist composition, the adhesion between the photoresist composition and the etch target film may be poor. Accordingly, a photoresist pattern may be peeled off from the etch target film after the etch target film is etched. On the other hand, when the compound of Formula 1 is added at more than 0.1 parts by weight based on 100 parts by weight of the photoresist composition, the adhesion of the photoresist composition to the etch target film may exceed an appropriate level. This may result in a footing phenomenon in which a developed photoresist pattern has a gently flabby lower part instead of a vertical profile and may cause scum of the photoresist pattern on the surface of a substrate.

The solvent may be any solvent that can dissolve the alkali-soluble resin, the photosensitive compound, and the compound of Formula 1 into a solution. In particular, a solvent that evaporates at an appropriate drying rate to form a uniform and flat photoresist film may preferably be used.

The solvent is not limited to a particular one and may include one of or a mixture of two or more of 3-methoxybutyl acetate, methyl methoxy propionate, butyl acetate, ethyl lactate, gamma-butyrolactone, and propylene glycol monomethyl ether acetate.

The solvent may be added such that the total weight of the photoresist composition is 100 parts by weight.

When necessary, the photoresist composition according to the current exemplary embodiment may selectively include additives such as a coloring, a dye, a plasticizer, a speed enhancer, and a surfactant. The addition of these additives may bring about performance enhancement, depending on characteristics of individual processes in which the photoresist composition is used.

Hereinafter, a method of forming a pattern according to an exemplary embodiment of the present invention will be described in detail with reference to the attached drawings.

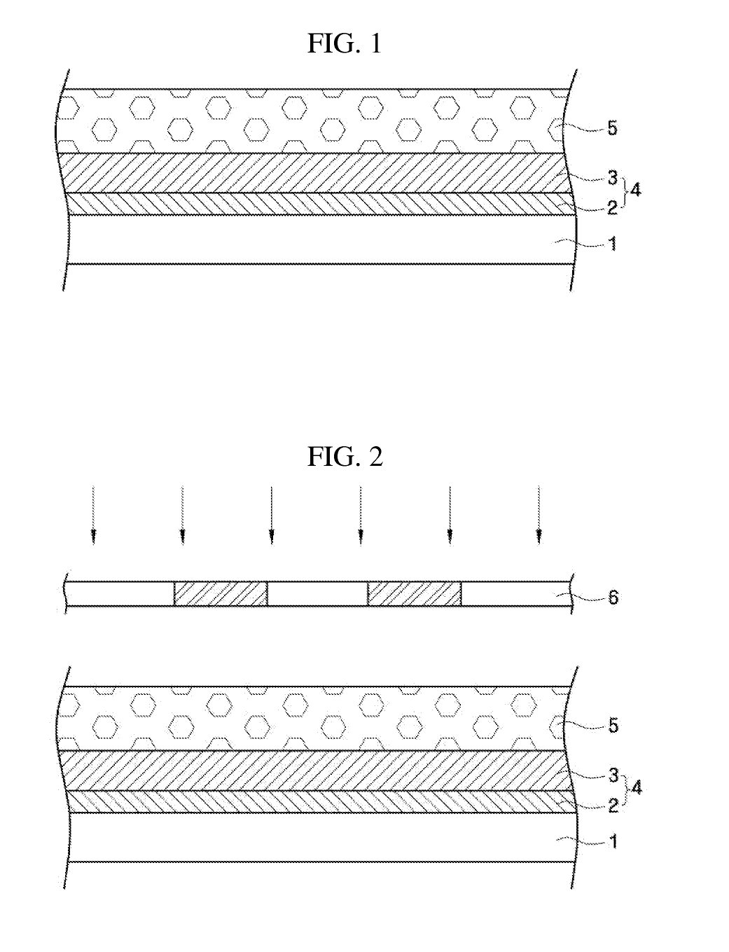

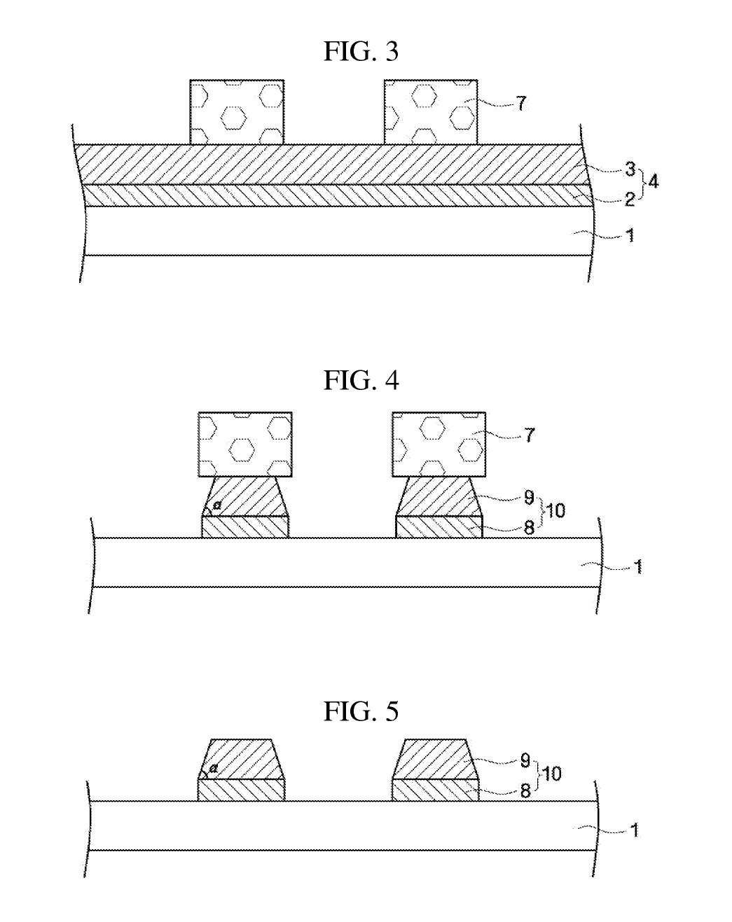

A method of forming a pattern according to an exemplary embodiment of the present invention will now be described with reference to FIG. 1, FIG. 2, FIG. 3, FIG. 4, and FIG. 5. FIG. 1, FIG. 2, FIG. 3, FIG. 4, and FIG. 5 are cross-sectional views of a method of forming a pattern according to an exemplary embodiment of the present invention.

Referring to FIG. 1, a substrate 1 is prepared on which an etch target film 4 is formed. The etch target film 4 may be a conductive film. For example, the etch target film 4 may consist of a titanium film 2 and a copper film 3 formed on the titanium film 2. A cleaning process for removing moisture or contaminants from the surface of the etch target film 4 or the substrate 1 may optionally be performed. The following description of the current exemplary embodiment is based on a case where the etch target film 4 has a double-film structure composed of two metal films. However, the etch target film 4 is not limited to the double-film structure. The etch target film 4 may be a single layer composed of only the copper film 3 or may be a multilayer composed of two or more metal layers, i.e., a combination of two or more of the titanium film 2, the copper film 3, and other metal layers.

Next, the etch target film 4 is coated with a photoresist composition, which includes an alkali-soluble resin, a photosensitive compound, 0.01 to 0.1 parts by weight of a compound of Formula 1, and a solvent, thereby forming a photoresist film 5. The photoresist composition is substantially the same as the photoresist composition according to the above-described exemplary embodiment of the present invention, and a detailed description thereof is not repeated.

The etch target film 4 may be coated with the photoresist composition by using a conventional method such as dipping, spraying, rotating, or spin coating. When spin coating is used to coat the etch target film 4 with the photoresist composition, the solid content of the photoresist composition solution may be controlled according to the type of a spinning device and a spinning method, thereby forming the photoresist film 5 of a desired thickness.

After the photoresist film 5 is formed, the substrate 1 having the photoresist film 5 may be heated in a first baking process. For example, the first baking process may be performed at approximately 20 to 100° C. The first baking process may be performed to vaporize the solvent without pyrolyzing solid components of the photoresist composition. It may be desirable to minimize the concentration of the solvent in the photoresist composition by using the first baking process. Thus, the first baking process may be performed until most of the solvent in the photoresist composition evaporates, and thus, only a thin film of the photoresist composition remains on the substrate 1.

Referring to FIG. 2, the substrate 1 is exposed to light. Specifically, a mask 6 or plate having a predetermined pattern is placed on a mask stage of an exposure device, and then the mask 6 is aligned over the substrate 1 having the photoresist film 5.

Next, the substrate 1 is exposed to light for a period of time, so that the photoresist film 5 formed on the substrate 1 selectively reacts with light that passes through the mask 6. An example of light that can be used in this exposure process includes ultraviolet (UV) light.

Referring to FIG. 3, a portion of the photoresist film 5, which was exposed to light, is removed using a developing solution, thereby forming a photoresist pattern 7. Specifically, the substrate 1 having the photoresist film 5 is fully dipped in a developing solution and is then left until the exposed portion of the photoresist film 5 dissolves completely or almost completely. Since the photoresist composition according to the current exemplary embodiment is a positive photoresist composition, the exposed portion of the photoresist film 5 is removed. The developing solution may be, for example, an alkaline developing solution. The alkaline developing solution is not limited to a particular one and may be, for example, an aqueous solution containing alkali hydroxide, ammonium hydroxide, or tetramethylammonium hydroxide (TMAH).

Next, referring to FIG. 4, the etch target film 4 formed under the photoresist pattern 7 is etched using the photoresist pattern 7 as an etch mask, thereby forming a pattern 10. Here, the etch target film 4 may be wet-etched or dry-etched.

When the etch target film 4 consists of the titanium film 2 and the copper film 3 formed on the titanium film 2, the ring structure of the compound of Formula 1 opens by a reduction reaction at an interface between the copper film 3 and the photoresist pattern 7. Accordingly, —COOH groups from both sides of the opened ring may be located in a plane. This facilitates the formation of a complex compound of copper and the compound of Formula 1, thereby increasing the adhesion of the copper film 3 to the photoresist pattern 7. Here, the titanium film 2 and the copper film 3 may simultaneously be etched using a fluorine-containing etching solution. The increased adhesion between the copper film 3 and the photoresist pattern 7 can prevent fluorine components of the etching solution from penetrating into the interface between the copper film 3 and the photoresist pattern 7. As a result, a taper angle α formed by sidewalls of a copper pattern 9 and the substrate 1 can be increased. The taper angle α of the copper pattern 9 may be, for example, 50° or more. A titanium pattern 8 may be formed under the copper pattern 9.

Next, referring to FIG. 5, the photoresist pattern 7 is removed using an appropriate stripper, thereby forming the desired pattern 10 on the substrate 1.

Hereinafter, a method of manufacturing a thin-film transistor (TFT) substrate according to an exemplary embodiment of the present invention will be described in detail with reference to the attached drawings.

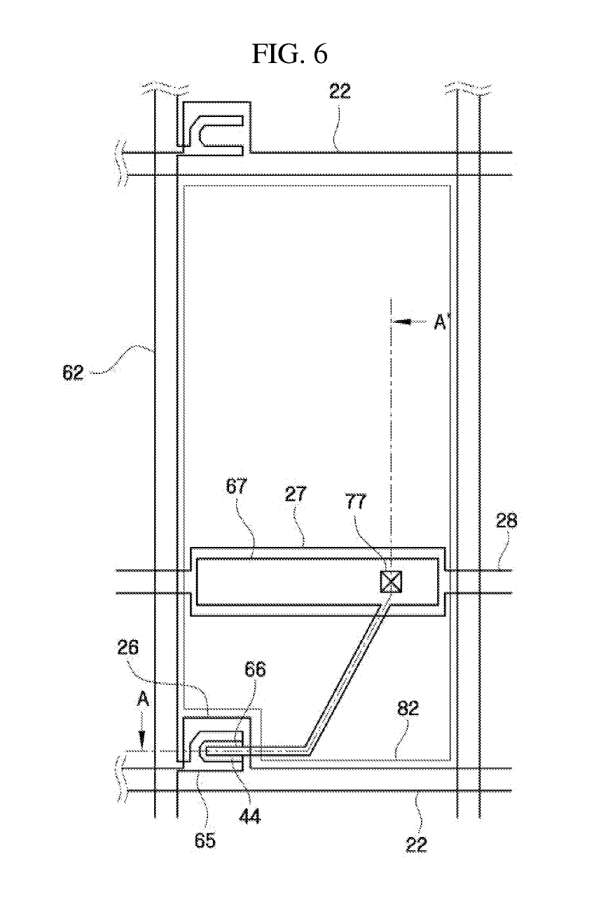

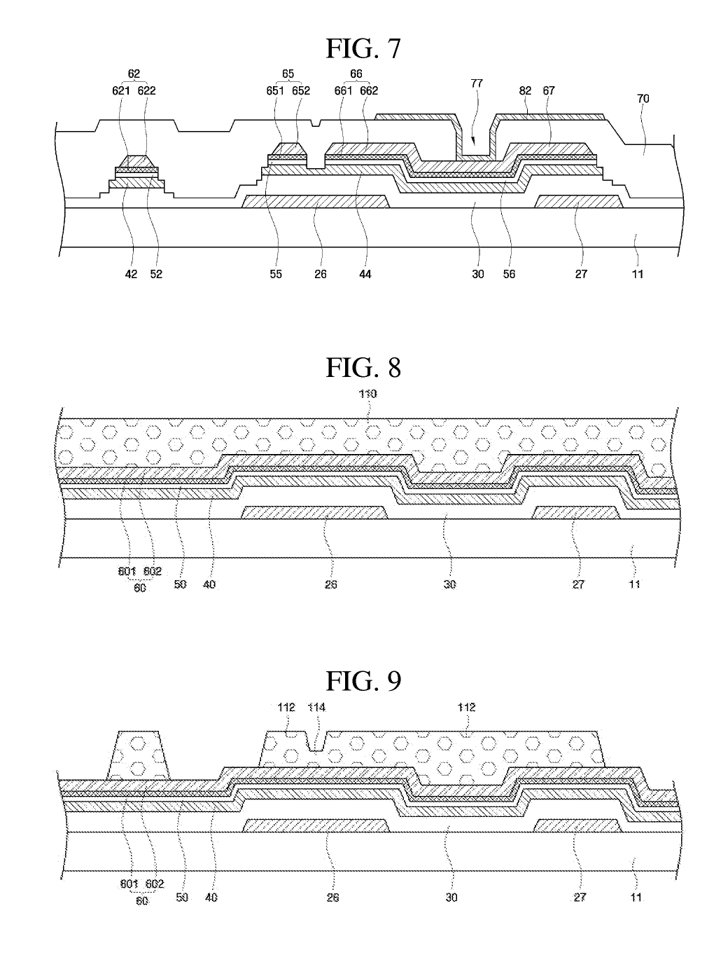

First, the structure of a TFT substrate manufactured using a manufacturing method according to an exemplary embodiment of the present invention will be described with reference to FIG. 6 and FIG. 7. FIG. 6 is a layout view of a TFT substrate manufactured using a manufacturing method according to an exemplary embodiment of the present invention. FIG. 7 is a cross-sectional view of the TFT substrate taken along line A-A′ of FIG. 6.

Referring to FIG. 6 and FIG. 7, a gate line 22 extends horizontally on a substrate 11, and a gate electrode 26 of a TFT is connected to the gate line 22 and projects from the gate line 22 in the form of a protrusion. The gate line 22 and the gate electrode 26 are referred to as gate wirings.

A storage line 28 is also formed on the substrate 11. The storage line 28 horizontally extends across a pixel region to be substantially parallel to the gate line 22. A storage electrode 27 having a large width is connected to the storage line 28. The storage electrode 27 is overlapped by a drain electrode extension portion 67 connected to a pixel electrode 82, which is described below, to form a storage capacitor that improves the charge storage capability of a pixel. The storage electrode 27 and the storage line 28 are referred to as storage wirings.

The shape and disposition of the storage wirings may vary. If sufficient storage capacitance can be generated by the overlapping of the pixel electrode 82 and the gate line 22, the storage wirings may not be formed.

The gate wirings 22 and 26 and the storage wirings 27 and 28 may be made of an aluminum (Al)-based metal, such as Al and an Al alloy, a silver (Ag)-based metal, such as Ag and a Ag alloy, a copper (Cu)-based metal such as Cu and a Cu alloy, a molybdenum (Mo)-based metal such as Mo and a Mo alloy, chrome (Cr), titanium (Ti), or tantalum (Ta).

In addition, the gate wirings 22 and 26 and the storage wirings 27 and 28 may have a multi-film structure composed of two conductive films (not shown) with different physical characteristics. One of the two conductive films may be made of metal with low resistivity such as an Al-based metal, a Ag-based metal, or a Cu-based metal in order to reduce a signal delay or a voltage drop of the gate wirings 22 and 26 and the storage wirings 27 and 28. The other one of the conductive films may be made of a different material, in particular, a material having superior contact characteristics with indium tin oxide (ITO) and indium zinc oxide (IZO), such as a Mo-based metal, Cr, Ti, or Ta. Examples of multi-film structures include a Cr lower film and an Al upper film and an Al lower film and a Mo upper film. However, the present invention is not limited thereto. The gate wirings 22 and 26 and the storage wirings 27 and 28 may be made of various metals and conductors.

A gate insulating film 30, which are made of silicon nitride (SiNₓ), is disposed on the gate wirings 22 and 26 and the storage wirings 27 and 28.

Semiconductor patterns 42 and 44, which are formed of a semiconductor such as hydrogenated amorphous silicon or polycrystalline silicon, are disposed on the gate insulating film 30.

Ohmic contact patterns 52, 55, and 56 are formed on the semiconductor patterns 42 and 44. The ohmic contact patterns 52, 55, and 56 are made of a material such as silicide or n+hydrogenated amorphous silicon doped with n-type impurities in high concentration.

A data line 62 and a drain electrode 66 are formed on the ohmic contact patterns 52, 55, and 56 and the gate insulating film 30. The data line 62 vertically extends to intersect the gate line 22. A source electrode 65 branches off from the data line 62 and extends onto the ohmic contact pattern 55. The drain electrode 66 is separated from the source electrode 65 and is formed on the ohmic contact pattern 56 to face the source electrode 65 with respect to the gate electrode 26 or a channel region of the TFT. The drain electrode 66 includes the drain electrode extension portion 67, which has a large area, extends from the drain electrode 66, and overlaps the storage electrode 27.

The data line 62, the source electrode 65, the drain electrode 66, and the drain electrode extension portion 67 are referred to as data wirings.

The data wirings 62, 65, 66, and 67 may have double-film structures composed of lower barrier patterns 621, 651, and 661 and upper conductive patterns 622, 652, and 662, respectively. Here, the lower barrier patterns 621, 651, and 661 may be made of, e.g., a titanium film. The upper conductive patterns 622, 652, and 662 may be made of a copper film with low resistivity. The lower barrier patterns 621, 651, and 661 can prevent copper components of the copper film from diffusing into the semiconductor patterns 42 and 44.

The source electrode 65 overlaps at least part of the semiconductor pattern 44. In addition, the drain electrode 66 faces the source electrodes 65 with respect to the channel region of the semiconductor pattern 44 and overlaps at least part of the semiconductor pattern 44.

The drain electrode extension portion 67 overlaps the storage electrode 27 to form a storage capacitor, and the gate insulating film 30 is interposed therebetween. When the storage electrode 27 is not formed, the drain electrode extension portion 67 may not be formed.

A passivation film 70 may be formed on the data wirings 62, 65, 66, and 67 and exposed portions of the semiconductor pattern 44. The passivation film 70 may be made of an organic material having photosensitivity and superior planarization properties, a low-k insulating material formed by plasma enhanced chemical vapor deposition (PECVD), such as a-Si:C:O or a-Si:O:F, or an inorganic material such as nitrogen oxide (SiNx). When the passivation film 70 is made of an organic material, an insulating film (not shown) made of SiNx or SiO₂ may additionally be disposed under the organic film in order to prevent the organic material of the passivation film 70 from contacting the exposed portions of the semiconductor pattern 44 between the source electrode 65 and the drain electrode 66.

A contact hole 77 exposing the drain electrode extension portion 67 is formed in the passivation film 70.

The pixel electrode 82 formed after the shape of a pixel is disposed on the passivation film 70. The pixel electrode 82 is electrically connected to the drain electrode extension portion 67 by the contact hole 77. The pixel electrode 82 may be made of a transparent conductor, such as ITO or IZO, or a reflective conductor such as Al.

In the TFT substrate manufactured according to the manufacturing method of the exemplary embodiment, distances that side surfaces of the lower barrier patterns 621, 652, and 662, side surfaces of the ohmic contact patterns 52, 55, and 56, and side surfaces of the semiconductor patterns 42 and 44 protrude beyond lower ends of side surfaces of the upper conductive patterns 622, 652, and 662 may be minimized.

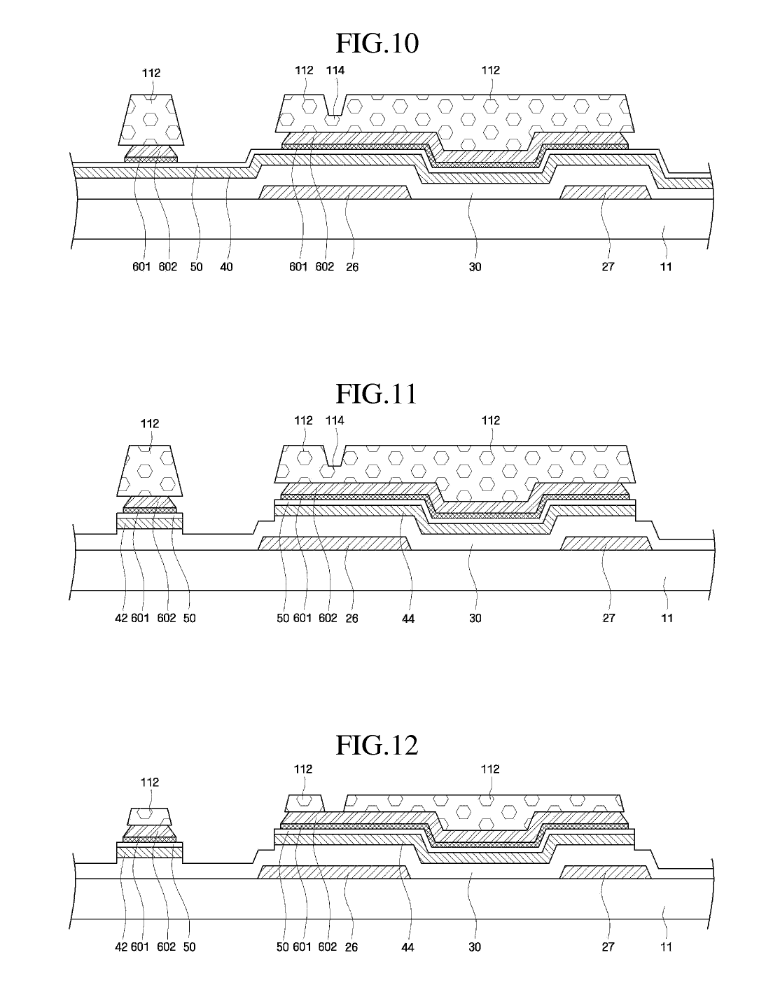

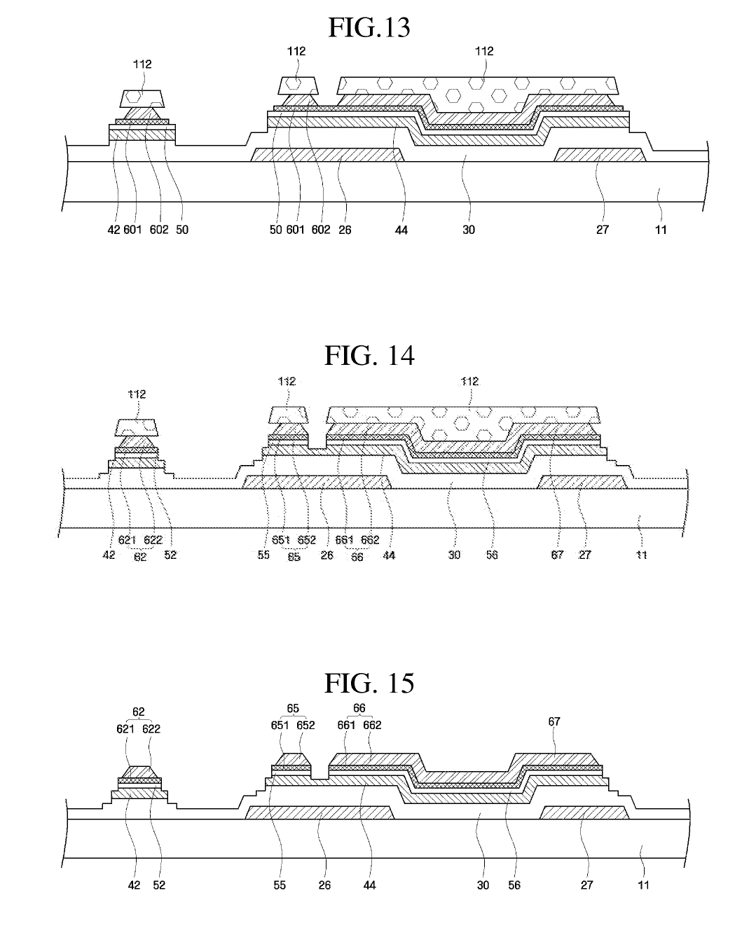

Hereinafter, a method of manufacturing a TFT substrate according to an exemplary embodiment of the present invention will be described in detail with reference to FIG. 6, FIG. 7, FIG. 8, FIG. 9, FIG. 10, FIG. 11, FIG. 12, FIG. 13, FIG. 14, and FIG. 15. FIG. 8, FIG. 9, FIG. 10, FIG. 11, FIG. 12, FIG. 13, FIG. 14, and FIG. 15 are cross-sectional views of a method of manufacturing the TFT substrate shown in FIG. 6 and FIG. 7.

First, referring to FIG. 6 and FIG. 8, a gate metal film (not shown) is formed on the substrate 11 and then patterned to form the gate line 22, the gate electrode 26, and the storage electrode 27. The gate metal film may be deposited using, e.g. sputtering. When the gate metal film is patterned to form the gate line 22, the gate electrode 26, and the storage electrode 27, wet etching or dry etching may be used. For wet etching, phosphoric acid, nitric acid, or acetic acid may be used as an etching solution. For dry etching, a chorine (Cl)-based etching gas, such as Cl₂ or BCl₃, may be used.

Next, the gate insulating film 30, a semiconductor layer 40, and an ohmic contact layer 50 are successively deposited on the substrate 11, the gate wirings 22 and 26, and the storage wirings 27 and 28 by using, e.g., chemical vapor deposition (CVD).

Then, a data wiring film 60 is formed on the ohmic contact layer 50 by using, e.g., sputtering. The data wiring film 60 may have a double-film structure composed of a lower barrier film 601 containing titanium and an upper conductive film 602 containing copper.

Next, the data wiring film 60 is coated with a photoresist composition, which includes an alkali-soluble resin, a photosensitive compound, 0.01 to 0.1 parts by weight of a compound of Formula 1, and a solvent, thereby forming a photoresist film 110. The photoresist composition and a method of forming the photoresist film 110 are substantially the same as the photoresist composition and the method of forming a pattern according to the above-described exemplary embodiments of the present invention so detailed descriptions thereof are not repeated.

Next, referring to FIG. 8 and FIG. 9, the photoresist film 110 is exposed to light through a mask and is then developed to form a photoresist pattern. The photoresist pattern includes a first region 114 and a second region 112 having different thicknesses. The second region 112 is disposed in regions where the data wirings are to be formed, and the first region 114, which is relatively thinner than the second region 112, is disposed in a region where a channel of a TFT is to be formed.

To vary the thickness of the photoresist pattern according to position as described above, various methods may be used. For example, a mask having slits, a lattice pattern, or a semi-transparent film may be used to control light transmittance.

Referring to FIG. 9 and FIG. 10, the data wiring film 60 is etched using the photoresist pattern 114 and 112 as an etch mask. This etching process may be a wet-etching process performed using a hydrofluoric acid (HF)-containing etching solution. That is, the upper conductive film 602 containing copper and the lower barrier film 601 containing titanium may be simultaneously etched using the HF-containing etching solution. The composition of the photoresist pattern according to the current exemplary embodiment is in contact with the copper of the upper conductive film 602 with sufficient adhesion to the copper. Thus, HF components of the etching solution can be prevented from penetrating into an interface between the photoresist pattern and the upper conductive film 602. Consequently, this can improve a taper angle of the etched upper conductive film 602. The taper angle of the etched upper conductive film 602 may be, for example, 50° or more.

Referring to FIG. 11, the ohmic contact layer 50 and the semiconductor layer 40 are etched using the photoresist patterns 114 and 112 as an etch mask. Here, a dry-etching process may be used. When the semiconductor layer 40 is etched, top surfaces of the exposed portions of the gate insulating film 30 may also be etched. In the dry-etching process, a fluorine (F)-based etching gas or a Cl-based etching gas may be used. Examples of the F-based etching gas include SF₆, XeF₂, BrF₂, and ClF₂, and examples of the Cl-based etching gas include HCl and Cl₂.

Referring to FIG. 11 and FIG. 12, the whole surface of the photoresist pattern is dry-etched, thereby removing the thin first region 114. In this case, the thickness and width of the thick second region 112 are reduced. Thus, side surfaces of the etched second region 112 may be located further inward than side surfaces of the etched lower barrier film 601. For the dry etching of the whole surface of the photoresist pattern 112 and 114, an ashing process using oxygen plasma may be performed. However, if the first region 114 is removed when the ohmic contact layer 50 and the semiconductor layer 40 are etched, the ashing process may be omitted.

Referring to FIG. 6, FIG. 7, FIG. 12, and FIG. 13, only the upper conductive film 602 of the data wiring film 60 is etched again by using the second region 112 of the photoresist pattern as an etch mask. Here, a wet-etching process may be used. An etching solution used to etch only the upper conductive film 602 may not contain HF components. Finally, the upper conductive patterns 622, 652, and 662 of the data wirings 62, 65, 66, and 67 are formed.

Referring to FIG. 13 and FIG. 14, the lower barrier film 601, the ohmic contact layer 50, and the semiconductor layer 40 are etched again by using the second region 112 of the photoresist pattern as an etch mask. Here, a dry-etching process may be used. Finally, the lower barrier patterns 621, 651, and 661 of the data wirings 62, 65, 66, and 67, the ohmic contact patterns 52, 55, and 56, and the semiconductor patterns 42 and 44 are formed. Here, top surfaces of the exposed portions of the gate insulating film 30 may be etched to a predetermined depth.

Referring to FIG. 14 and FIG. 15, the second region 112 of the photoresist pattern is removed. Here, an ashing process using oxygen plasma may be performed to remove the second region 112 of the photoresist pattern.

In the method of manufacturing the TFT substrate according to the current exemplary embodiment, a top surface of the lower barrier film 601 is partially exposed by the secondary etching of the upper conductive film 602. Then, when the lower barrier film 601, the ohmic contact layer 50, and the semiconductor layer 40 are secondarily etched, the side surfaces of the lower barrier patterns 621, 651, and 661, the side surfaces of the ohmic contact patterns 52, 55, and 56, and the side surfaces of the semiconductor patterns 42 and 44 may protrude further outward than the lower ends of side surfaces of the upper conductive patterns 622, 652, and 662.

Here, if the initially etched upper conductive film 602 has a smaller taper angle due to the poor adhesion between the upper conductive film 602 and the photoresist pattern 112 and 114, the width of the top surface of a portion of the lower barrier film 601, which is exposed by the secondary etching of the upper conductive film 602, increases. As a result, the distances that the side surfaces of the lower barrier patterns 621, 651, and 661, the side surfaces of the ohmic contact patterns 52, 55, and 56, and the side surfaces of the semiconductor patterns 42 and 44 protrude beyond the lower ends of the side surfaces of the upper conductive patterns 622, 652, and 662 may increase.

For example, when the initially etched upper conductive film 602 has a taper angle of approximately 16.6°, the horizontal distances from the lower ends of the side surfaces of the upper conductive patterns 622, 652, and 662 to the side surfaces of the lower barrier patterns 621, 651, and 661 may be approximately 1.40 μm. On the other hand, when the initially etched upper conductive film 602 has a taper angle of approximately 58.74°, the horizontal distances from the lower ends of the side surfaces of the upper conductive patterns 622, 652, and 662 to the side surfaces of the lower barrier patterns 621, 651, and 661 may be approximately 0.164 μm. That is, it can be understood that a greater taper angle of the initially etched upper conductive film 602 results in a noticeable reduction in the horizontal distances from the lower ends of the side surfaces of the upper conductive patterns 622, 652, and 662 to the side surfaces of the lower barrier patterns 621, 651, and 661.

Therefore, the taper angle of the initially etched upper conductive film 602 of the data conductive film 60 can be increased by improving the adhesion of the upper conductive film 602 to the photoresist pattern 114 and 112. Accordingly, the horizontal distances from the lower ends of the side surfaces of the upper conductive patterns 622, 652, and 662 to the side surfaces of the lower barrier patterns 621, 651, and 661, the side surfaces of the ohmic contact patterns 52, 55, and 56, and the side surfaces of the semiconductor patterns 42 and 44 can be reduced. Consequently, a black matrix formed to correspond to the data line 62 can be minimized, thereby improving an aperture ratio.

Next, referring to FIG. 7, the passivation film 70 is formed using PECVD or reactive sputtering.

Then, the contact hole 77 is formed using a photolithography process to expose the drain electrode extension portion 67. Next, a transparent conductive film is deposited, and a photolithography process is performed on the transparent conductive film, thereby forming the pixel electrode 82 which is connected to the drain electrode extension portion 67 by the contact hole 77.

Hereinafter, the present invention will be described in greater detail by way of specific examples and comparative examples.

### Example 1

### Preparation of an Alkali-Soluble Resin

A first cresol novolac resin was obtained by the condensation reaction of a mixture of 36 mol % m-cresol and 64 mol % p-cresol in the presence of oxalic acid and formaldehyde. In addition, a second cresol novolac resin was obtained by the condensation reaction of a mixture of 57 mol % m-cresol and 43 mol % p-cresol in the presence of oxalic acid and formaldehyde. Then, an alkali-soluble resin was prepared by mixing the first cresol novolac resin and the second cresol novolac resin in a ratio of 60:40 by weight.

Preparation of a Photosensitive Compound:

A photosensitive compound was prepared by mixing (a) a first ester of 1 mole of 2,3,4,4′-tetrahydroxy benzophenone and 2.3 moles of naphthoquinone-1,2-diazide-5-sulfonyl chloride with (b) a second ester of 1 mole of 2,3,4,4′-tetrahydroxy benzophenone and 1.5 moles of naphthoquinone-1,2-diazide-5-sulfonyl chloride in a weight ratio of 50:50.

Preparation of a Photoresist Composition:

A photoresist composition was prepared by dissolving 18.4 parts by weight of the alkali-soluble resin, 5.3 parts by weight of the photosensitive compound, and 0.03 parts by weight of maleic anhydride, in which R is hydrogen in the following Formula 1, in 76.27 parts by weight of a solvent mixture of 3-methoxybutyl acetate and ethyl lactate, stirring until dissolution results, and then filtering using a 0.1 μm filter.

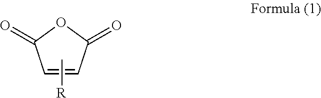

### Example 2

A photoresist composition was prepared in the same manner as in Example 1 except 0.05 parts by weight of the compound of Formula 1 and 76.25 parts by weight of the solvent were used.

### Example 3

A photoresist composition was prepared in the same manner as in Example 1 except 0.07 parts by weight of the compound of Formula 1 and 76.23 parts by weight of the solvent were used.

### Comparative Example 1

A photoresist composition was prepared in the same manner as in Example 1 except 0.005 parts by weight of the compound of Formula 1 and 76.295 parts by weight of the solvent were used.

### Comparative Example 2

A photoresist composition was prepared in the same manner as in Example 1 except 0.15 parts by weight of the compound of Formula 1 and 76.15 parts by weight of the solvent were used.

### Comparative Example 3

A photoresist composition was prepared in the same manner as in Example 1 except the compound of Formula 1 was not used while 76.30 parts by weight of the solvent were used.

Evaluation of Photoresist Patterns

A photoresist pattern was formed using each of the photoresist compositions prepared in Example 1, Example 2, and Example 3 and Comparative Example 1, Comparative Example 2, and Comparative Example 3. Specifically, a titanium film was formed to a thickness of 300 Å on a substrate, and a copper film was formed to a thickness of 3,000 Å on the titanium film. Then, the copper film was coated with each of the photoresist compositions of Example 1, Example 2, and Example 3 and Comparative Example 1, Comparative Example 2, and Comparative Example 3 to a thickness of 1.9 μm. Next, the substrate coated with the photoresist compositions was exposed to UV light and then dipped for 60 seconds in an aqueous solution containing 2.38 parts by weight of tetramethylammonium hydroxide. Accordingly, each of the corresponding photoresist compositions exposed to the UV light was removed, thereby forming a photoresist pattern. Then, an HF-containing etching solution was sprayed over the substrate having the photoresist pattern to etch the titanium film and the copper film. For each of the photoresist compositions, nine photoresist patterns having a width of 5 μm and nine photoresist patterns having a width of 3 μm were formed and evaluated.

The adhesion of each photoresist pattern to a copper pattern after the etching of the copper pattern and titanium pattern was evaluated by observing whether the photoresist pattern peeled off at an interface between the photoresist pattern and the copper pattern based on a cross-section of the photoresist pattern and the copper/titanium pattern interrogated by scanning electronic microscope (SEM). The results are shown in Table 1.

Characteristics of each photoresist pattern are indicated in Table 1 as follows:

“o” indicates a case where 8 to 9 photoresist patterns did not peel off;

“Δ” indicates a case where 4 to 7 photoresist patterns did not peel off;

“X” indicates a case where 3 or less photoresist patterns did not peel off; and

“F/S” indicates the occurrence of a footing phenomenon, in which a photoresist pattern has a gently flabby lower part instead of a vertical profile because the adhesion of the photoresist pattern to the copper pattern exceeds an appropriate level, and the occurrence of scum of the photoresist pattern on the surface of the substrate.

TABLE 1

| | Photoresist pattern | Photoresist pattern |
|---|---|---|
| | with a width of 5 μm | with a width of 3 μm |
| Example 1 | ◯ | ◯ |
| Example 2 | ◯ | ◯ |
| Example 3 | ◯ | ◯ |
| Comparative example 1 | □ | X |
| Comparative example 2 | F/S | F/S |
| Comparative example 3 | X | X |

As shown in Table 1, photoresist patterns formed using the photoresist compositions of Example 1, Example 2, and Example 3 had superior adhesion to the copper film. Thus, the photoresist patterns hardly peeled off even after the copper film and the titanium film were etched. On the other hand, photoresist patterns formed using the photoresist compositions of Comparative Example 1 and Comparative Example 2, in which the compound of Formula 1 was added at less than 0.01 parts by weight, had poor adhesion to the copper film. Thus, most of the photoresist patterns peeled off. Photoresist patterns formed using the photoresist composition of Comparative Example 2, in which the compound of Formula 1 was added at more than 0.1 parts by weight, had the footing phenomenon and scum thereof since their adhesion to the copper film exceeded an appropriate level.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A photoresist composition, comprising:
an alkali-soluble resin;
a photosensitive compound;
a solvent; and
0.01 to 0.1 parts by weight of a compound represented by Formula 1: 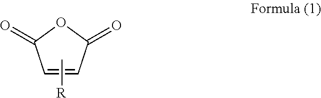
wherein R comprises one of hydrogen, an alkyl having 1 to 10 carbon atoms, a cycloalkyl having 4 to 8 carbon atoms, and a phenyl group.

2. The photoresist composition of claim 1, wherein the compound of Formula 1 is in the range of 0.03 to 0.07 parts by weight.

3. The photoresist composition of claim 1, wherein the alkali-soluble resin is in the range of 10 to 30 parts by weight.

4. The photoresist composition of claim 3, wherein the photosensitive compound is in the range of 1 to 15 parts by weight.

5. The photoresist composition of claim 1, wherein the compound of Formula 1 comprises phthalic anhydride in which R comprises a phenyl group.

6. The photoresist composition of claim 1, wherein the compound of Formula 1 comprises maleic anhydride in which R comprises hydrogen.

7. The photoresist composition of claim 6, wherein the alkali-soluble resin comprises a cresol novolac resin obtained by a condensation reaction of a mixture of m-cresol and p-cresol in the presence of oxalic acid and formaldehyde.

8. The photoresist composition of claim 7, wherein the photosensitive compound comprises an ester of 2,3,4,4′-tetrahydroxy benzophenone and naphthoquinone-1,2-diazide-5-sulfonyl chloride.

9. The photoresist composition of claim 8, wherein the solvent comprises a mixture of 3-methoxybutyl acetate and ethyl lactate.

10. A method of forming a pattern, the method comprising:
forming a photoresist film by coating an etch target film with a photoresist composition that comprises an alkali-soluble resin, a photosensitive compound, a solvent, and 0.01 to 0.1 parts by weight of a compound represented by Formula 1: 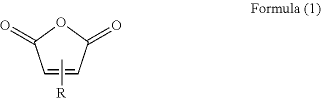
wherein R comprises one of hydrogen, an alkyl having 1 to 10 carbon atoms, a cycloalkyl having 4 to 8 carbon atoms, and a phenyl group;
exposing the photoresist film to light;
forming a photoresist pattern by developing the photoresist film; and
etching the etch target film by using the photoresist pattern as an etch mask.

11. The method of claim 10, wherein the compound of Formula 1 is in the range of 0.03 to 0.07 parts by weight.

12. The method of claim 10, wherein the alkali-soluble resin is in the range of 10 to 30 parts by weight.

13. The method of claim 12, wherein the photosensitive compound is in the range of 1 to 15 parts by weight.

14. The method of claim 10, wherein the compound of Formula 1 comprises phthalic anhydride in which R comprises a phenyl group.

15. The method of claim 10, wherein the compound of Formula 1 comprises maleic anhydride in which R comprises hydrogen.

16. The method of claim 10, wherein the etch target film comprises a titanium film and a copper film disposed on the titanium film.

17. The method of claim 16, wherein etching of the etch target film comprises simultaneously etching the titanium film and the copper film using a hydrofluoric acid-containing etching solution.

18. A method of manufacturing a thin-film transistor substrate, the method comprising:
sequentially forming a semiconductor layer and a wiring film on a substrate;
forming a photoresist film by coating the wiring film with a photoresist composition comprising an alkali-soluble resin, a photosensitive compound, a solvent, and 0.01 to 0.1 parts by weight of a compound represented by Formula 1: 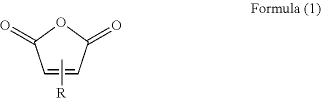
wherein R comprises one of hydrogen, an alkyl having 1 to 10 carbon atoms, a cycloalkyl having 4 to 8 carbon atoms, and a phenyl group;
forming a photoresist pattern, which comprises a first region and a second region that is thicker than the first region and disposed on both sides of the first region, by exposing the photoresist film to light and developing the exposed photoresist film;
performing a first etching of the wiring film and the semiconductor layer by using the photoresist pattern as an etch mask;
removing the first region of the photoresist pattern; and
performing a second etching of the wiring film and the semiconductor layer by using the second region of the photoresist pattern, which remains on the wiring film, as an etch mask.

19. The method of claim 18, wherein the wiring film comprises a lower film and an upper film, wherein the lower film comprises titanium and the upper film comprises copper.

20. The method of claim 19, wherein the first etching of the wiring film comprises simultaneously etching the lower film and the upper film using an hydrofluoric acid-containing etching solution.
